(19) United States
(12) Patent Application Publication
(10) Pub. No.: US 2016/0307770 A1
(43) Pub. Date: Oct. 20, 2016

(54) METHOD AND DEVICE FOR TREATING OBJECTS WITH A LIQUID

(71) Applicant: Jörg HOFER-MOSER, Penk (AT)

(72) Inventors: Jorg HOFER-MOSER, Villach (AT); Manuel LINDER, Villach (AT)

(21) Appl. No.: 15/103,025

(22) PCT Filed: Nov. 26, 2014
(86) PCT No.: PCT/AT2014/000209

§ 371 Date: Jun. 9, 2016

(30) Foreign Application Priority Data
Dec. 9, 2013 (AT) A 946/2013

(51) Int. Cl. H01L 21/306; H01L 21/02; H01L 21/687; H01L 21/67

(52) U.S. Cl. CPC H01L 21/30604; H01L 21/6715; H01L 21/67051; H01L 21/6708; H01L 21/02052; H01L 21/67248; H01L 21/67259; H01L 21/68707; H01L 21/67253; H01L 21/67109

(57) ABSTRACT

In the treatment of a semiconductor wafer (8), a treatment medium, in particular an etching or cleaning liquid, is applied to the semiconductor wafer (8) from a nozzle (11). In this process, the temperature, the concentration and/or the amount of medium applied in the unit of time are controlled depending on the location (7) at which the medium is being applied to the semiconductor wafer (8). In this manner, uniform treatment of the semiconductor water (8) is achieved because irregularities in the semiconductor wafer (8) can be compensated.

The invention relates to a method for treating objects with a liquid and furthermore a device with which the method according to the invention can be carried out.

In treating objects with a liquid, the problem arises that the temperature, the concentration and/or the amount of liquid which is applied onto the surface of the object which is to be treated must be altered depending on the respectively prevailing conditions. In so doing, it can be necessary to alter the temperature, the concentration and/or the amount of liquid during the treatment of the surface of the object, in order to alter these in accordance with differences in the structure and/or the composition of the object.

This problem arises for example in the etching of semiconductor wafers and in the cleaning of etched semiconductor wafers.

The etching of semiconductor wafers with etching medium (etching liquids) generally takes place in that an etching medium is applied onto the semiconductor wafer, which is arranged on a mount and is set in rotation by the mount.

The arrangements currently used for the etching of semiconductor wafers are too slow with regard to controlling the temperature of the etching liquid, in order to quickly alter or quickly adjust the temperature during the process.

Through the slow (etching) devices used in the prior art, it is solely possible to keep the temperature of the etching liquid stable. An active influence on the uniformity of the temperature is not possible in the prior art. Thereby, no uniform temperature distribution is produced on the semiconductor wafer, which impairs the uniformity of the result of the etching.

Furthermore, the problem arises that in the current prior art at the start of the etching process (activation process), etching medium applied onto the surface of the object (semiconductor wafer) which is to be treated is colder than is necessary for a proper treatment process. All medium-carrying parts are only in thermal equilibrium after some time.

The invention is based on the problem of proposing a method and a device suitable for carrying out the method, by which during the treatment of the object (e.g. wafer) the temperature and/or the concentration and/or the amount of the liquid can be altered as desired, in order to compensate differences in the structure of the object which is to be treated, in particular uniformity differences, in the surface of a semiconductor wafer.

This problem is solved according to the invention by a method which has the features of claim 1.

In so far as the device is concerned, the problem on which the invention is based is solved by a device which has the features of the independent claim, directed to the device.

Preferred and advantageous embodiments of the invention are the subject of the subclaims.

Through the method according to the invention, it is achieved in its embodiments that the uniformity of the result of the treatment of the object, in particular the uniformity over the surface of the semiconductor wafer, is improved, because it is possible to adapt the temperature and/or the concentration and/or the amount of the treatment medium which is applied onto the object. Thus, a reduction of waste occurs, because an increase in the quality is achieved.

Furthermore, in an advantageous manner the invention permits smaller structures to be treated.

Furthermore, in the method according to the invention, a constant heating of the liquid to the required temperature is dispensed with, so that energy can be saved.

In an embodiment of the invention, through inductive heating of the medium (liquid) which is used for treating the object, the possibility is opened up to use small heating elements, so that masses which are to be temperature-controlled are reduced. Through induction heating, a heating solely on the material surface is achieved, so that heat can be transmitted by convention. This produces a rapid reaction to changes in the temperature of the medium necessary during the carrying out of the method.

As the medium (liquid) used for the treatment must, at all events, be cooled, a cooler can be used, which operates for example with Peltier elements. These Peltier elements can be used both in a heating and also in a cooling manner, so that the dynamics of the method and device according to the invention is improved.

Furthermore, in embodiments the invention permits the amount of medium (liquid) delivered in the unit of time to the application arrangement, in particular its nozzle, to be controlled by a through-flow controller, i.e. permits the through-flow of the medium to be altered. This produces the possibility, with a small through-flow, to heat the medium over a longer period of time and, with a high through-flow, to heat the medium over a shorter period of time. By coupling these principles with the local position of the application arrangement, in particular its nozzle, relative to the object which is to be treated, an advantageous mode of operation is produced in the treatment of objects with a medium (a liquid), in particular in the etching and/or cleaning of semiconductor wafers.

In detail, the invention permits in embodiments a temperature manipulation of medium (liquid) applied onto the surface of the object, wherein the medium can be heated or cooled.

By controlling the through-flow amount of the medium (liquid) applied onto the surface which is to be treated, in particular in semiconductor etching systems, an additionally possible manipulation is produced, in order to adapt the method conditions to the circumstances.

Preferably, within the invention, the heating of the medium (liquid) used for the treatment takes place by convective heat transfer of a preferably chemically inert surface, heated by induction, which is flowed around by the medium (liquid for the treatment). In particular, the use of an arrangement for heating in the form of a continuous flow heater is preferred here, because the transfer takes place predominantly by convection instead of by heat conduction or heat radiation. Thus, a particularly effective heat transfer is produced, which permits a rapid heating of the medium (the liquid) which is used for the treatment.

In the method according to the invention, heating, cooling and controlling of the through-flow amount are carried out with arrangements which are associated with the duct for delivering the treatment medium to the application arrangement, in particular its nozzle.

Further details and features of the invention will emerge from the following description of preferred example embodiments with the aid of the drawings. There are shown:

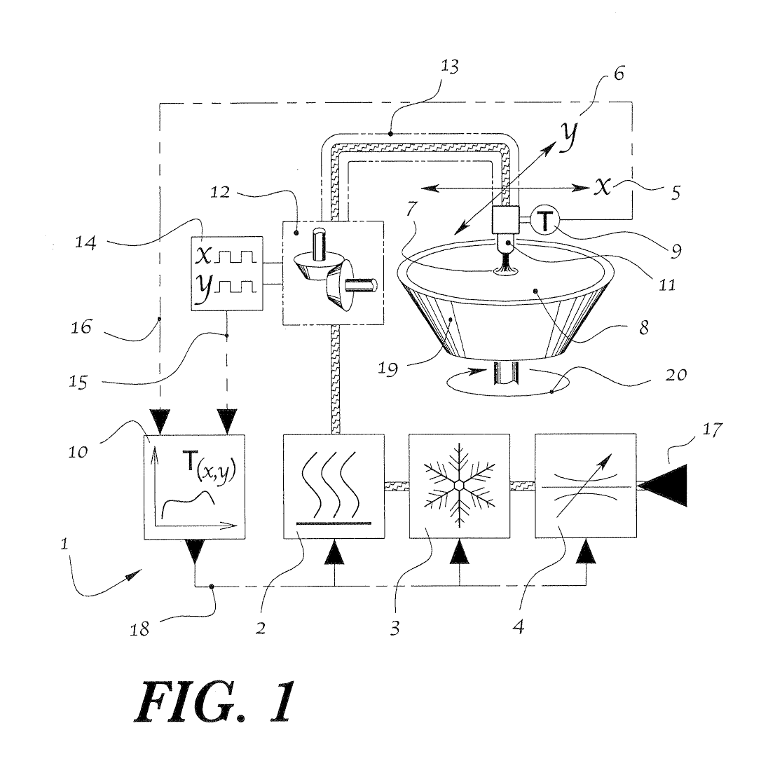

FIG. 1 diagrammatically a device for carrying out the method of the invention,

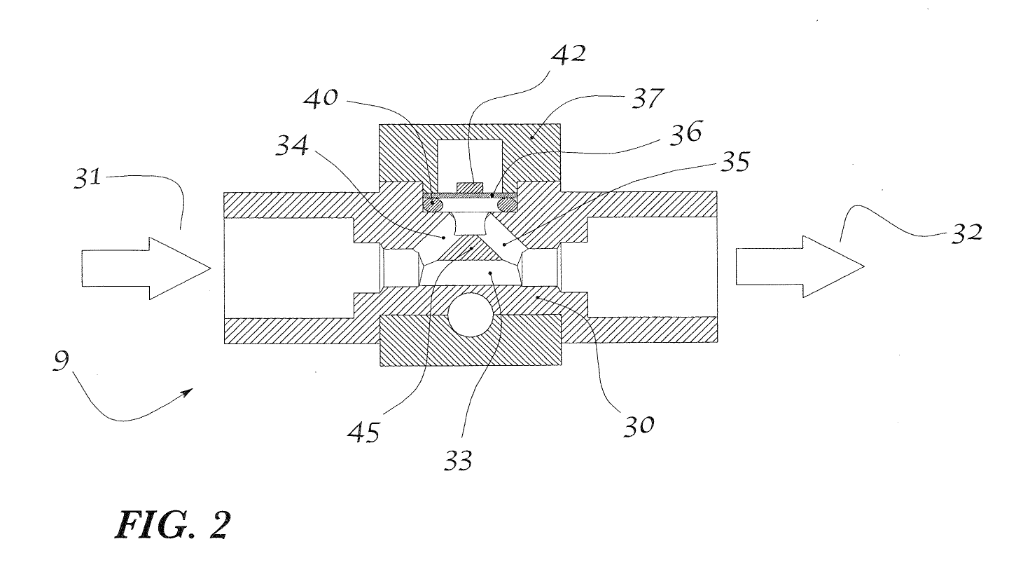

FIG. 2 in section a temperature sensor which can be used for detecting the temperature in the region of the application arrangement,

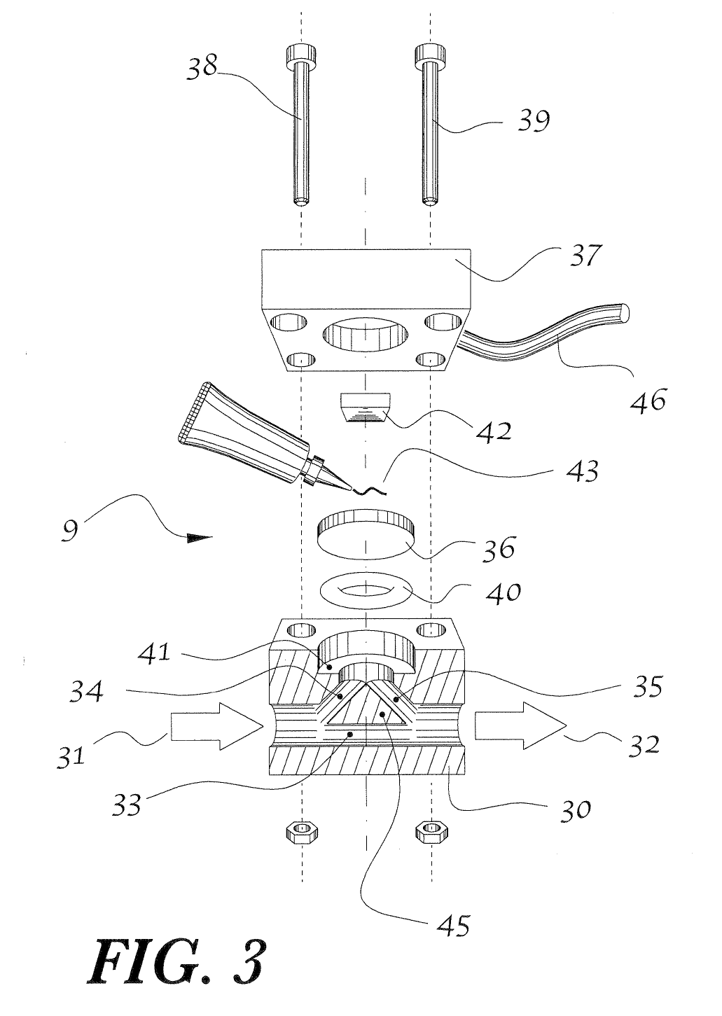

FIG. 3 the temperature sensor in exploded illustration,

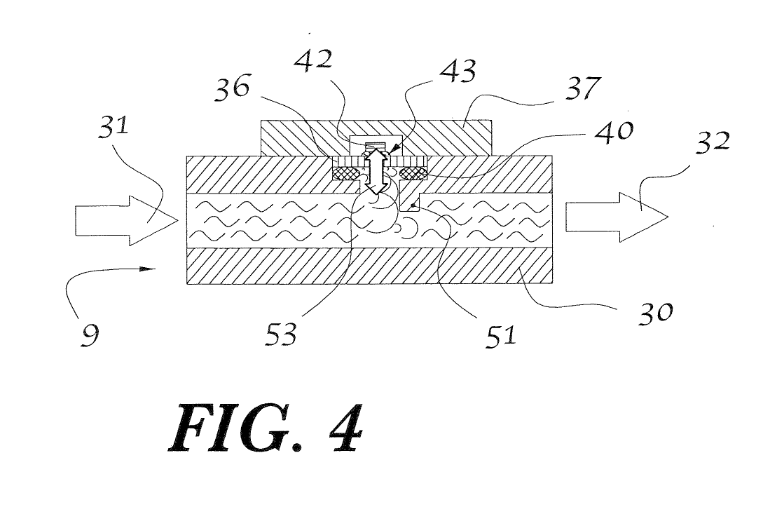

FIG. 4 in section another embodiment of a temperature sensor,

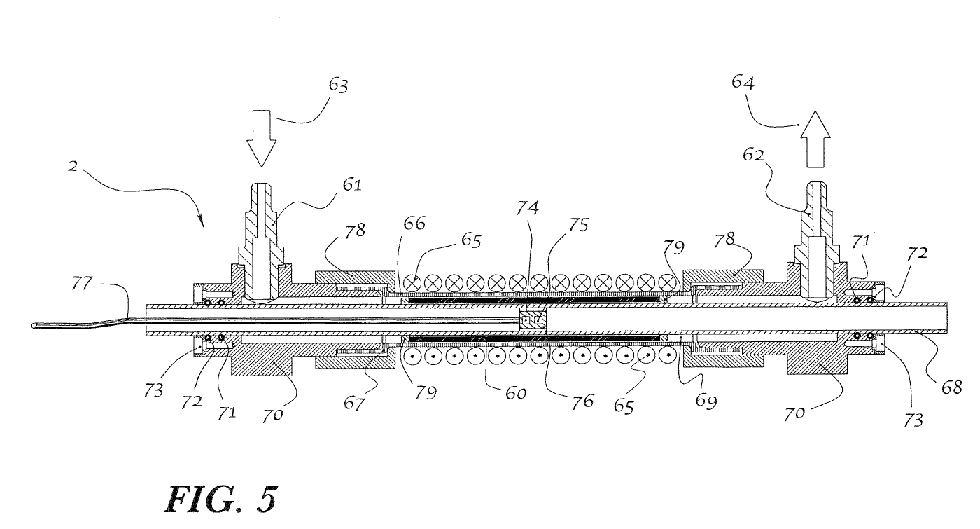

FIG. 5 diagrammatically in section an arrangement for heating the liquid,

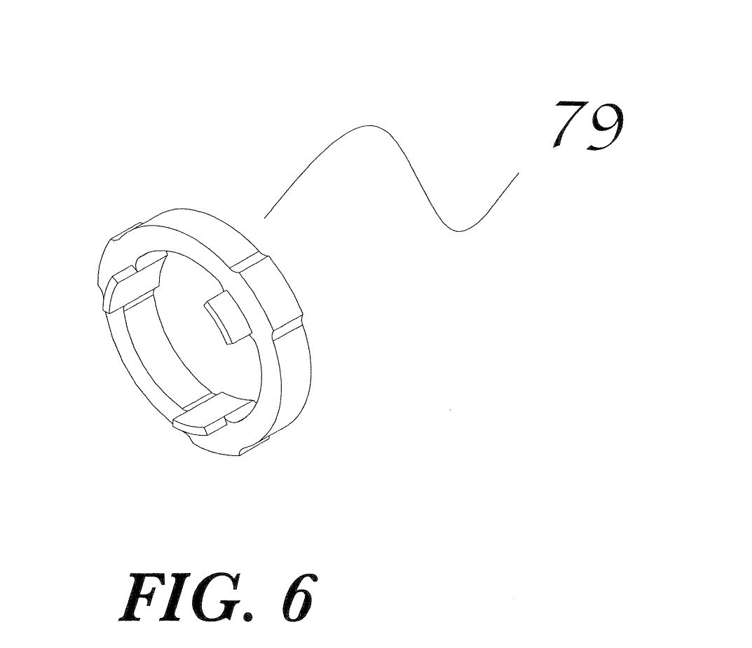

FIG. 6 a detail of the arrangement of FIG. 5,

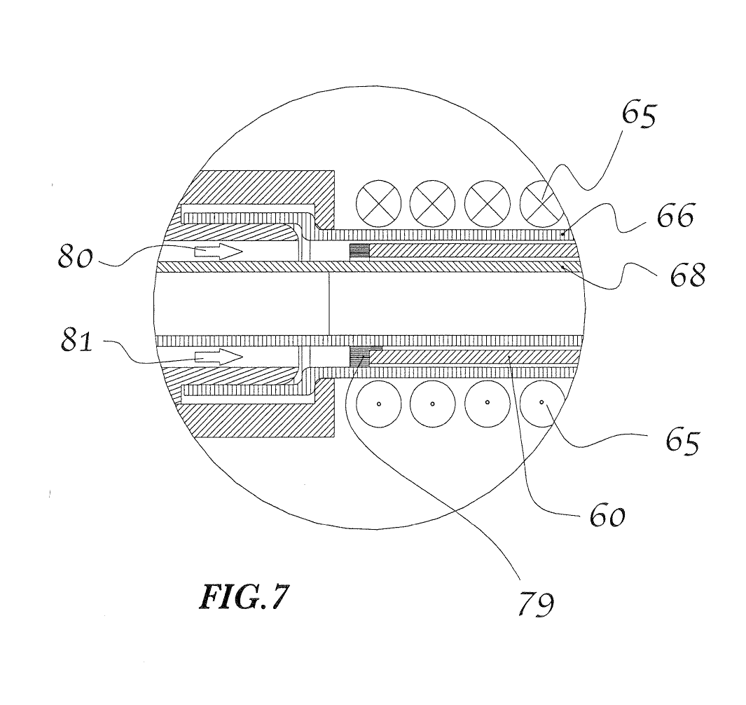

FIG. 7 a further detail of the arrangement of FIG. 5,

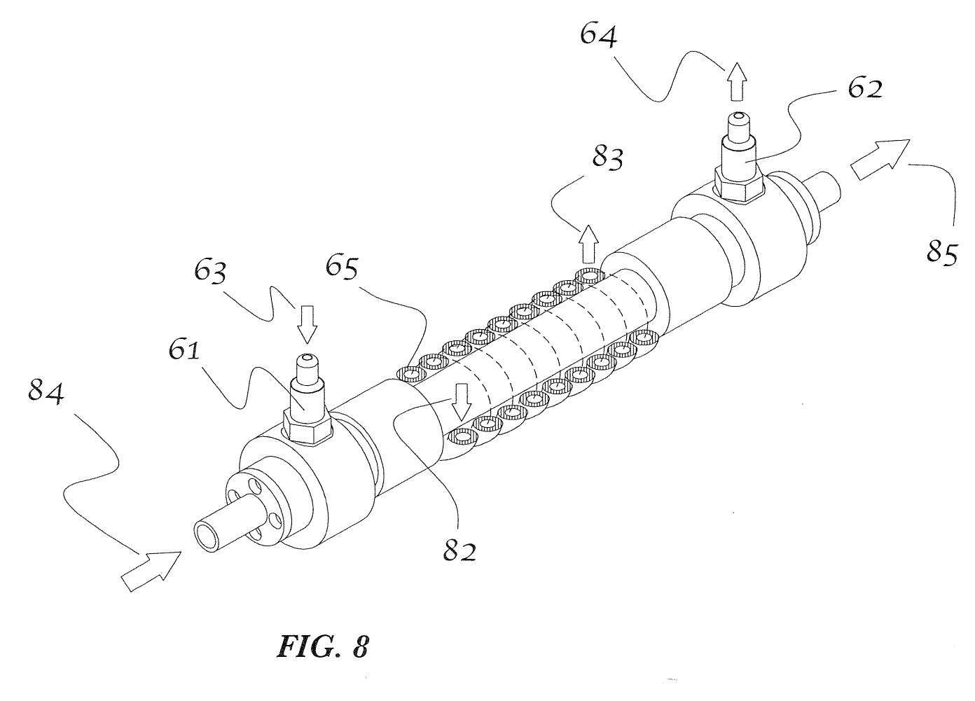

FIG. 8 the arrangement of FIG. 5 in oblique view, partially in section,

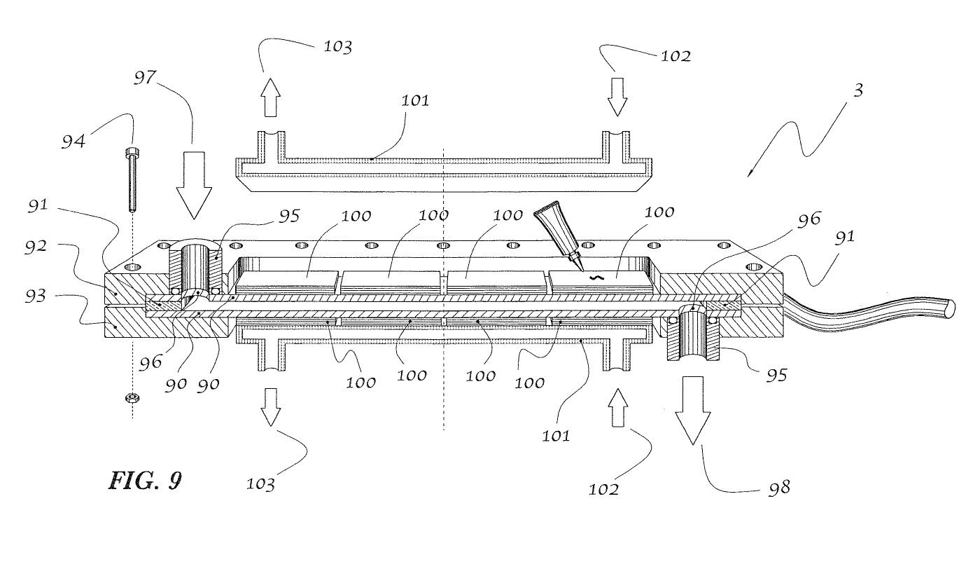

FIG. 9 in section an arrangement for cooling,

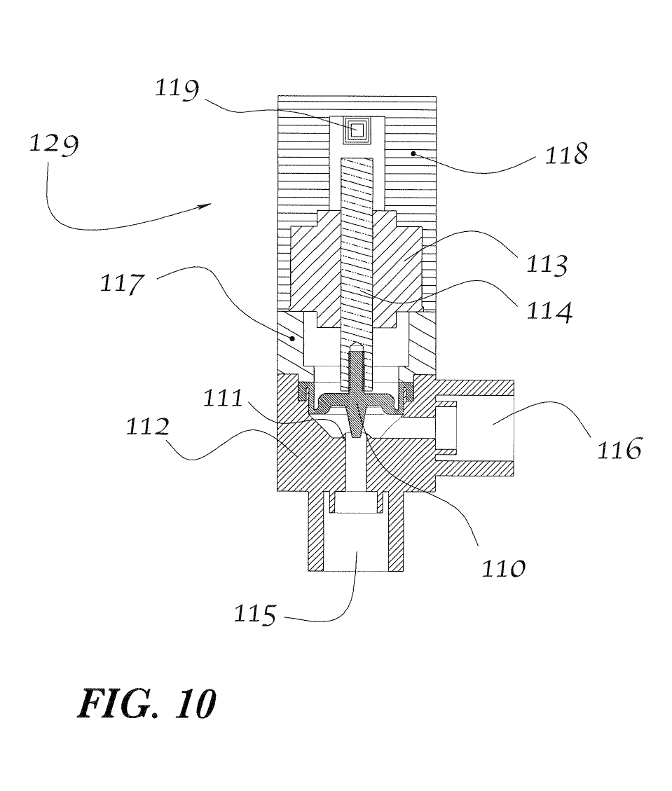

FIG. 10 a arrangement for controlling the through-flow amount and

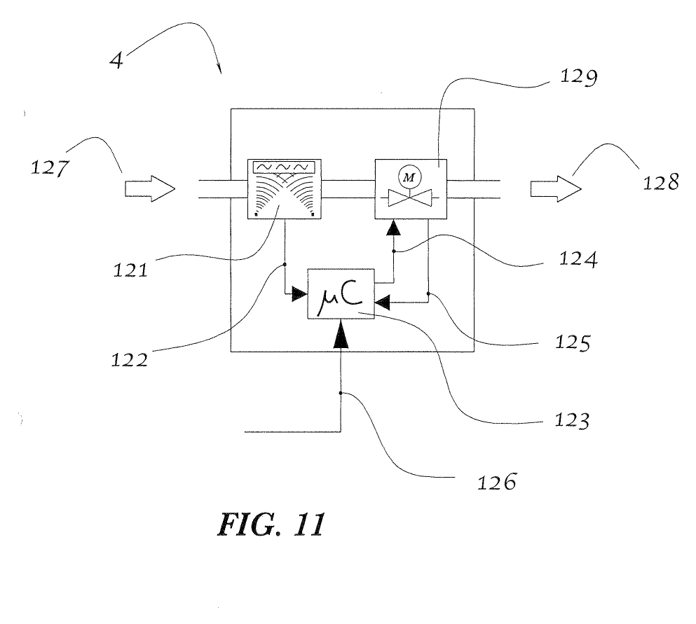

FIG. 11 an arrangement for manipulating the through-flow amount,

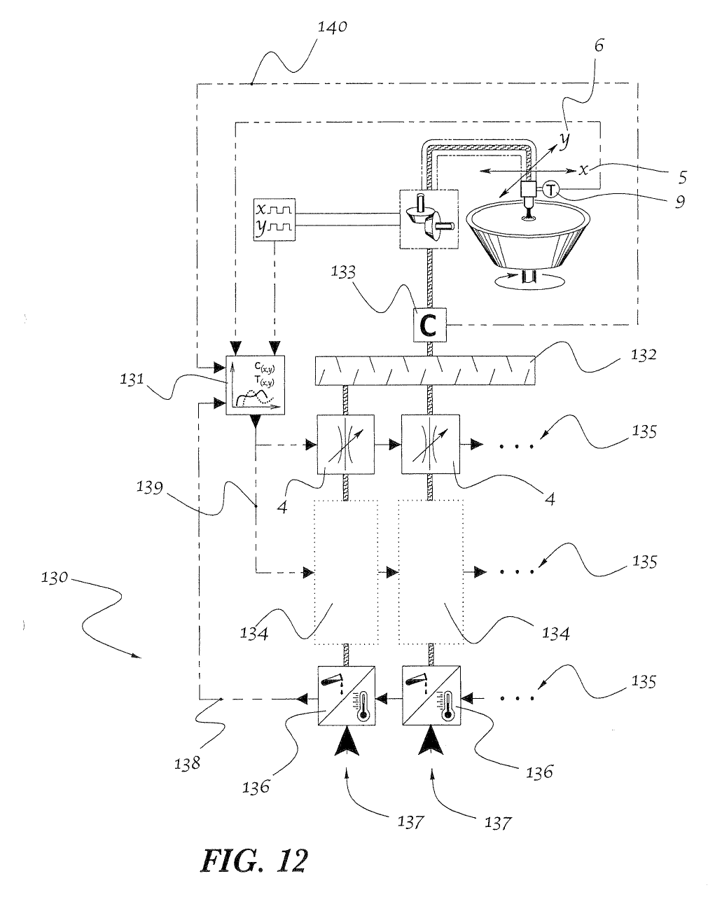

FIG. 12 a modified embodiment of a device according to the invention and

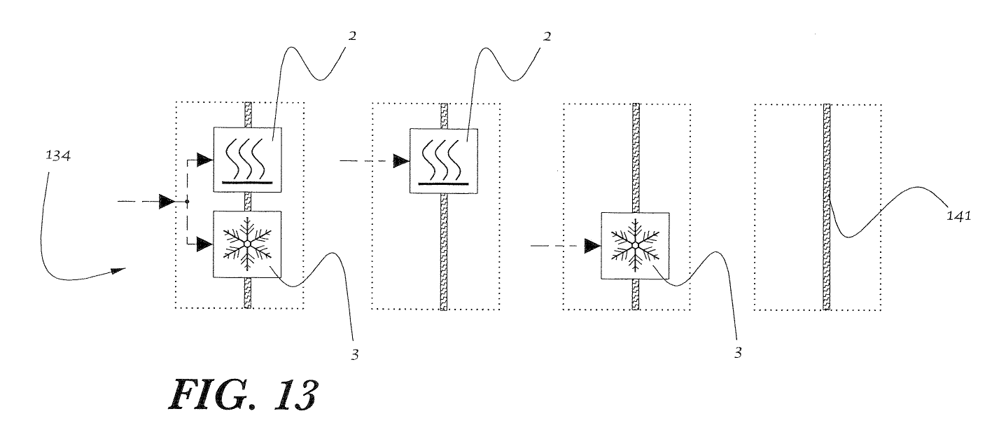

FIG. 13 combinations of arrangements of the device according to the invention.

A device 1 according to the invention, shown in FIG. 1, which is suitable for carrying out the method of the invention, comprises a chuck 19, onto which a semiconductor wafer 8 is placed. The chuck 19 can be embodied in any desired manner and can be coupled with a drive (not shown), which sets the chuck 19 in rotation (arrow 20).

Associated with the chuck 19 is an arrangement for the application of a treatment medium, in the example, a treatment liquid, which arrangement comprises a nozzle 11 which is connected rigidly with actuators 12 via an arrangement 13. The actuators 12 allow the nozzle 11 of the application arrangement to be moved over the arrangement 13 relative to the surface of the object which is to be treated, in the example embodiment a semiconductor wafer 8. The movement possibilities in direction X and direction Y are symbolised in FIG. 1 by arrows 5 and 6.

Treatment fluid, an etching medium in the etching of semiconductor wafers, is delivered to the nozzle 11 via a duct 17. Associated with the duct 17 are an arrangement 4 for the control of through-flow amount, a cooling arrangement 3 and an arrangement 2 for heating the liquid.

The current position of the nozzle 11 and therefore the location 7 of the liquid application are detected by incremental encoders 14 which are associated with the actuators 12. The incremental encoders 14 emit data concerning the current position of the application nozzle 11 relative to the surface of the wafer 8 to a control circuit 10.

A temperature sensor 9 is associated with the duct 17 for delivering treatment liquid directly in front of the nozzle 11, which temperature sensor emits to the control circuit 10 data concerning the temperature of the liquid detected by it. The temperature parameters 16 emitted to the control circuit 10 from the temperature sensor 9 and the position parameters 15 emitted from the incremental encoders 14 are assigned from the control circuit 10 as a control algorithm to the arrangements 4, associated with the duct 17, for the through-flow amount control, to the arrangement for cooling 3 and to the arrangement 2 for heating.

In this manner, a highly dynamic position-coupled temperature control and quantity control is possible, which includes the advantage of a thermal optimization of all medium-carrying parts.

The device 1 shown in FIG. 1 for temperature- and/or through-flow manipulation of liquid delivered from the nozzle 11 operates depending on the position of the nozzle 11 of the application arrangement relative to the object which is to be treated, in the example the semiconductor wafer 8. Thus, an improvement to the surface regularity during the cleaning and in wet-chemical and temperature-dependent etching, for example of wafer surfaces, is achieved.

It is particularly advantageous if within the invention, as arrangement 2 for heating, an arrangement is used which operates on an induction basis and which heats by convention the liquid flowing through the arrangement 2.

A temperature sensor 9, which is particularly suited with the device according to the invention for carrying out the method according to the invention for detecting the temperature of the treatment liquid applied onto the object, is explained below with the aid of FIGS. 2 and 3.

The temperature sensor 9 shown in FIGS. 2 and 3 permits a quick detection of the temperature of media, wherein the media can be in particular chemically highly reactive gases, chemically highly reactive liquids or chemically highly reactive, flowing materials. The temperature sensor is constructed so that the medium flow (arrow 31) entering into its body 30 is divided into two partial flows by a body 45 provided in the flow path. One partial flow flows through a substantially straight channel 33 and a second partial flow flows through an angled channel comprising two sections 34 and 35. The partial flow flowing through the channel sections 34 and 35 strikes at an acute angle of, for example, 45° onto a disc-shaped body 36 and then flows through the section 35 out again from the body 30 of the temperature sensor 9 (arrow 32).

By the dividing into the partial flows, a reduction is produced of the pressure in the region of the inlet into the temperature sensor 9.

The disc-shaped body 36 is pressed by the upper part 37 of the temperature sensor 9 through screws 38 and 39 via a seal 40 onto a sealing surface 41 of the body 30 of the temperature sensor 9, so that a hermetically closed system is produced.

The medium-touching parts of the temperature sensor 9 are preferably made of chemically resistant materials, wherein for example the disc-shaped body 36 preferably consists of (polycrystalline) diamond, glassy carbon, sapphire or silicon carbide, if applicable with CVD coating (Chemical Vapour Deposition), the seal 40 consists preferably of perfluoroelastomer (FFKM), and the body 30 of the temperature sensor 9 consists preferably of polytetrafluoroethylene (PTFE).

The detecting of the temperature in the temperature sensor 9 takes place via a temperature detector 42, which is for example a platinum thin layer measuring resistor. The temperature detector 42 is preferably glued by means of a heat-conducting adhesive 43 (two-component epoxy resin) with the disc-shaped body 36, so that a good heat transfer exists. A line 46 leads away from the temperature detector 42, which line emits the data 16, detected by the temperature detector 42, to the control circuit 10 via the line shown in FIG. 1.

Another embodiment of a temperature sensor 9 is shown in FIG. 4 and is described below.

In this embodiment of a temperature sensor 9, turbulent flows are forced through an obstacle 51 provided in the flow channel 11, which in the embodiment of the temperature sensor 9 shown in FIG. 6 produces a rapid temperature exchange between disc 36 and medium. As in the embodiment shown in FIGS. 2 and 2a, the disc 36 is pressed by the upper part 37 of the temperature sensor with intercalation of a seal 40 onto the support surface 41 in the body 30 of the temperature sensor 9. The embodiment of a temperature sensor 9 shown in FIG. 6 likewise permits, as the embodiment of FIGS. 2 and 2a, a rapid temperature exchange between medium flowing through the temperature sensor 9 and the temperature detector 42, as is indicated by the arrow 53.

The temperature sensor 9 can also be constructed so as to be multiply remanent. For this, a plurality of temperature detectors 42 are glued on the disc 36 of the temperature sensor 9, the temperature signals of which are compared by means of a checking program (software algorithm), in order to identify any temperature deviations occurring by ageing phenomena, wherein these temperature differences are not to exceed a certain difference. An exceeding of the minimum temperature difference is indicated by a checking system by a signal. A changing of the temperature difference can be indicated visually or acoustically. If several temperature detectors 42 are arranged on the disc 36, a multipolar cable 46 is to be used for the passing on of the data which the temperature detectors 42 detect.

An arrangement 2, operating on induction basis, for the heating of liquid flowing through the duct 17 to the nozzle 11, is described below with reference to FIGS. 5 to 8:

The arrangement 2 shown in FIGS. 5 to 8 for heating a liquid or gaseous flowing medium has a hollow-cylindrical heating element 60, which is flowed around at its inner side and its outer side by the medium, which flows in (arrow 63) and off (arrow 64) via connections 61, 62. The heating element 60, which consists for example of glassy carbon, is heated by alternating magnetic fields, in particular on its outer side (“skin effect”). The frequency of the magnetic field can move for example in the range of 100 kHz to 1 MHz. The magnetic field is generated by a coil 65. The coil 65 is separated by a tube 66 from the heating element 60 and from the through-flowing medium. The transfer of energy therefore occurs in a contactless manner, which signifies a considerable advantage compared with conventional heating elements, which require an electrical contact and therefore have to be sealed with respect to the medium which is to be treated. The interior 67 is separated hermetically by means of an inner tube 68 from the reactor chamber 69 and via a sealing system with body 70, seal 71, clamping ring 72 and press part 73. The press part 73 serves for the introduction of measuring sensors 74 (PT 100, PT 1000) and safety sensors 75 (e.g. TCO Thermal Cut Off), because final magnetic energy in the axial centre is only minimal, so that the sensors can be damaged due to strong electromagnetic fields and offer a good access for the better monitoring of the heating element. This is advantageous for a safety-relevant operation.

The sensors 74 and 75 are preferably arranged centrally and are embedded in heat-conducting material 76, wherein cables 77 exit from the sensors 74, 75. A widened outer tube 20 is pressed by means of a screw connection 78 onto the body 70 and forms a hermetically sealed region from the reactor chamber 69 to the outer region.

The arrangement 2 is mirror-symmetrical with respect to its centre plane, therefore the same applies for the outlet 62 as for the inlet 61. Outlet 62 and inlet 61 can also be provided with a screw fitting. In order to keep the heating element 60 at a uniform, concentric distance from the inner tube 68 and from the outer tube 66, a spacer ring 79 (FIGS. 10 and 11) is inserted. A particular advantage is the small distance, because thus a quick heat transfer occurs from the heating element 60 to the medium which flows through the arrangement 2.

The inflowing medium is divided into an outer flow region 80 and into an inner flow region 81, so that the heating element 60 is flowed around completely.

The arrangement 2 is designed so that all components consist of materials with low thermal inertia.

In FIG. 8 the arrangement 2 is shown, wherein the coil 65, which preferably consists of a soft copper tube, is illustrated partially in section in an oblique view. In FIG. 8 the inlet 82 is also shown for a cooling liquid, and the outlet 83 for a cooling liquid, by which the coil 65 is cooled.

The described structure of the arrangement 2 in addition offers the possibility, in the inner region, of flushing away or respectively blowing out corrosive gases occurring through diffusion (e.g. hydrogen fluoride) by nitrogen, which enters via a flushing inlet 84 and exits again through the flushing outlet 85.

An arrangement 3 for cooling is explained below with the aid of FIG. 9:

The arrangement 3 shown in FIG. 9 for the cooling of liquid media has two plates 90 aligned over one another and parallel to one another. The space between the plates 90 is sealed by an edge seal 91, wherein the seal 91 keeps the plates 90 at a distance from one another. The distance of the plates 2 from one another is advantageously selected so that a good heat transfer is possible onto the medium which is to be cooled, which is assisted by reaching a turbulent flow. The plates 90 can be made from sapphire, diamond, glassy carbon or from silicon carbide, if applicable with a silicon carbide layer (SiC) deposited thereon.

The plates 2 and 3 are held between an upper part 92 and a lower part 93 of the arrangement 3, which are held together by screws 94. A pipe section 95 is screwed into an opening of the upper plate 92 and aligned with a hole 96 in the upper plate 90 and is sealed with respect to the plate 90 by a ring seal (e.g. O-ring). The pipe section 95 serves as inlet for the medium which is to be cooled (arrow 97). A pipe section 95 is likewise screwed into the lower plate 2, which pipe section communicates with an opening 96 in the lower plate and is sealed with respect to the plate 90 by a ring seal (e.g. O-ring). The medium, after it has flowed through the space between the plates 90, can emerge out from the arrangement 3 again through the pipe section 95 (arrow 98). Peltier elements 100 are associated with the plates on both sides, so that heat extracted from the medium is emitted via the Peltier elements to a cooling body 101 which is arranged on the upper side and on the lower side. The cooling elements 101 have respectively an inlet 102 and an outlet 103, so that they can be flowed through by a cooling medium.

In FIG. 9 it is also indicated that the Peltier elements are brought by heat-conducting adhesive 104 into good heat-conducting connection to the cooling bodies 101.

The device shown in FIG. 9 can basically also be used for heating a medium flowing through the arrangement 3, after reversing the polarity of the Peltier elements 100.

An arrangement 4 for controlling through-flow amount is explained below with the aid of FIG. 10:

The arrangement 4 for controlling the through-flow of a medium comprises a membrane 110, which on one side has a needle-shaped, tapering projection, the distance of which to the valve seat 111 which is connected in one piece with a body 112 can be altered by means of an adjustment device 113, 114. The adjustment device preferably comprises a stepping motor 113, the spindle 114 of which represents a drive for the membrane 110. The spindle 114 does not rotate and is moved only linearly by means of a rotating sleeve incorporated in the motor 113. Medium is introduced into the inlet 115 and exits again via the outlet 116. The bodies 117 and 118 serve merely for the positioning of the stepping motor 113 and for sealing the membrane 110, for which screw connections, which are not shown, are provided. A sensor 119 detects the distance of the membrane 110 or respectively its play from the valve seat 111, which data are delivered to the control.

An embodiment of the through-flow manipulation 4 illustrated diagrammatically in FIG. 11 determines the through-flow by means of a through-flow sensor 121 (for example an ultrasonic through-flow sensor). The values detected thereby are delivered via a signal line 112 to a control 123, which via a further control line 124 operates the actuator 113, 114 (stepping motor) of the through-flow controller 129, which in turn passes on its current position to the control through a position control via a control line 125. The through-flow of the medium via inlet 127 and through outlet 128 can be preset from the exterior via a main control line 126.

In order to permit a rapid controlling of the temperature of the medium, in relation to the position of the nozzle 11 relative to the wafer 8, it is necessary to create a previously known chronological, local temperature profile, so that the respectively required temperature of the medium can be maintained. For this, advantageously a cooling arrangement is used, which compensates local temperature differences and in so doing the current setting of the system and of the medium which is to be treated is taken into consideration, in order to avoid any interference factors, heat sinks etc.

The amended embodiment, illustrated in FIG. 12, of a device 130 according to the invention is an extension of the device 1 according to FIG. 1. The device 130 also comprises arrangements 134 for controlling the temperature and arrangements 4 for controlling the through-flow amount of the treatment medium (treatment liquid) applied through the nozzle 11 onto the wafer 8.

In addition, the device 130 according to FIG. 12 comprises arrangements by which the concentration of the treatment medium (etching liquid) can be altered depending on the position of the nozzle 11 and therefore of the location 7, in which treatment medium is applied onto the wafer 8.

The device provided for this comprises a sensor 133, which detects the concentration of the treatment medium. For example, the concentration sensor 133 is a conventional pH-measuring apparatus or a spectrometer, by which concentration of the respectively used treatment liquid can be determined.

In detail, the device 130 operates in the setting of the concentration as a function of the nozzle 11 as follows:

The components of the treatment medium are delivered via ducts 137 and the defined concentration- and temperature values in medium sources 136 are passed on to the control/regulation 131 via a control line 138. A software algorithm converts into control signals temperature values delivered via the lines 138, the concentration values delivered via the line 140 and the values of the temperature, which are detected by the temperature sensor 9. These control signals are passed on via control lines 139 to the components 134 for controlling the temperature 134 and the device 4 for controlling the through-flow amount. The media flows are delivered to a mixing device 132, which is constructed in particular as a static mixer, and are mixed with one another, wherein with the use of a static mixer a quick intermixing can be achieved for reaching the desired temperature and/or concentration with the predetermined amount.

The points 135 drawn in FIG. 12 adjacent to the through-flow amount controllers 4, the controllers for the temperature 134 and the media sources 136 indicate that also more than two of these components can be provided.

In FIG. 13 different combination possibilities of arrangements for heating 2 and arrangements 3 for cooling are indicated. Further possibilities of combining the variants illustrated in FIG. 13 are conceivably the arrangements 134 for adjusting the temperature by heating and cooling of the medium, wherein also the variant without an arrangement for controlling the temperature 134 is indicated at 141. When this variant, which is indicated at 141, is implemented, the adjusting of the temperature can takes place in an analogous manner to the adjusting of the concentration via through-flow controllers, without separate arrangements for heating and for cooling, when the temperatures in the media sources 136 of the medium flows 137 are differently high to a sufficient extent.

1. A method for treating objects (8) with a medium, in particular a liquid, characterized by the steps
application of the medium onto the surface of the object (8) to be treated by means of an application arrangement (11), which is moved relative to the object (8) to be treated over the surface of the object (8) to be treated,
controlling of characteristics of the medium to be applied onto the object to be treated depending on the position of the application arrangement (11) relative to the surface of the object (8) to be treated,
controlling of the temperature of the medium to be applied onto the object (8) to be treated, wherein the temperature is detected by means of a temperature sensor (9), which is associated with the application arrangement, in particular its nozzle (11).

2. The method according to claim 1, characterized in that the amount of the medium to be applied in the unit of time onto the object (8) to be treated is controlled.

3. The method according to claim 1, characterized in that the concentration of the medium to be applied onto the object (8) to be treated is controlled.

4. The method according to claim 1, characterized in that a semiconductor wafer (8) is treated.

5. The method according to claim 4, characterized in that the semiconductor wafer (8) is etched.

6. The method according to claim 4, characterized in that the semiconductor wafer (8) is cleaned.

7. The method according to claim 1, characterized in that the object (8) to be treated is set in rotation (20) during the treatment.

8. The method according to claim 1, characterized in that the medium, in particular the liquid, is applied onto the object (8) from a nozzle (11) of an application arrangement.

9. The method according to claim 8, characterized in that the application arrangement, in particular its nozzle (11), is moved by at least one actuator (12) relative to the object (8) to be treated and that the position of the application arrangement, in particular its nozzle (11), is detected by incremental encoders (14).

10. The method according to claim 1, characterized in that the temperature of the medium is detected immediately before the application onto the object (8) to be treated, in particular immediately before its exit from the nozzle (10) of the application arrangement.

11. The method according to claim 1, characterized in that the medium, in particular the liquid, is heated or cooled.

12. The method according to claim 11, characterized in that for controlling the temperature, components of the medium to be applied onto the object (8) to be treated, in particular of the liquid, which have different temperatures from one another, are mixed.

13. The method according to claim 1, characterized in that for controlling the concentration of the medium to be applied onto the object to be treated, in particular of the liquid, which have different concentrations from one another, are mixed.

14. The method according to claim 1, characterized in that the position of the application arrangement, in particular detected by incremental encoders (14), and the temperature of the medium, in particular detected by the temperature sensor (9), are assigned to a control circuit (10) and that the control circuit (10) controls the temperature of the medium, the amount of medium which is delivered to the application arrangement in the unit of time, and/or the concentration of the medium.

15. A device for carrying out the method according to claim 1 with a mount (19) for the object (8) to be treated, with an arrangement (11) for applying the medium onto the object (8) to be treated, to which arrangement a duct (13) for the medium leads, and with an actuator (12) for moving the application arrangement (11) relative to the object (8) to be treated, characterized by
at least one sensor for detecting at least one characteristic of the medium,
at least one incremental encoder (14) which, for detecting the position of the application arrangement, is associated with the actuator,
a control circuit (10), which is functionally connected with at least one sensor and with the incremental encoder (14),
an arrangement (4), associated with the duct (13) for the medium, for controlling the amount of medium flowing in the unit of time through the duct (13), which arrangement (4) is functionally connected with the control circuit (10),
a sensor (9), which is associated with the application arrangement (11) at the site of the exit of the medium from it and which detects the temperature of the medium.

16. The device according to claim 15, characterized in that the mount for the object to be treated is a carrier in the manner of a chuck (19) for semiconductor wafers (8), with which a drive for rotating (20) the mount (19) is associated.

17. The device according to claim 15, characterized in that the application arrangement comprises a nozzle (11), from which medium is applied onto the surface of the object (8) to be treated.

18. The device according to claim 15, characterized in that arrangements (2, 3) for heating and cooling the medium are associated with the duct for the medium, which arrangements are functionally connected with the control circuit (10).

19. The device according to claim 15, characterized in that a sensor (133) for detecting the concentration of the medium, in particular of the liquid, is provided.

20. The device according to claim 15, characterized in that a mixing device (132) is provided for the mixing of partial flows of the medium, which partial flows have different temperatures and/or concentrations from one another.

21. The device according to claim 15, characterized in that the arrangement (2) for heating the medium, in particular the liquid, is an arrangement heating the medium by convection, which operates on the basis of induction.

22. The device according to claim 18, characterized in that the arrangement (3) for cooling the medium comprises at least one Peltier element (100).

23. The device according to claim 15, characterized
by a housing (30), in which a flow channel (33, 34, 35) is provided for the medium, the temperature of which is to be detected,
that the flow channel (33) in the region of a temperature sensor is divided into two partial channels (34, 35), which combine again after flowing past the temperature sensor (42) and
that the temperature sensor (42) is arranged in heat-conducting contact on a disc-shaped body (36).

24. The device according to claim 15, characterized in that in the flow channel of the temperature sensor an obstacle (51) is provided, generating turbulences in the through-flowing medium, wherein the obstacle (51), in relation to the flow direction of the medium, is provided after the disc (36) on which the temperature sensor (42) is arranged.
